(19) United States
(12) Patent Application Publication
(10) Pub. No.: US 2019/0341516 A1
(43) Pub. Date: Nov. 7, 2019

(54) MICROSTRUCTURED ZnO COATINGS FOR IMPROVED PERFORMANCE IN Cu(In, Ga)Se2 PHOTOVOLTAIC DEVICES

(71) Applicant: The Government of the United States of America, as represented by the Secretary of the Navy, Arlington, VA (US)

(72) Inventors: Jesse A. Frantz, Washington, DC (US); Jason D. Myers, Alexandria, VA (US); Robel Y. Bekele, Washington, DC (US); Jasbinder S. Sanghera, Ashburn, VA (US)

(21) Appl. No.: 16/512,450

(22) Filed: Jul. 16, 2019

Related U.S. Application Data
(62) Division of application No. 14/701,857, filed on May 1, 2015.
(60) Provisional application No. 61/986,940, filed on May 1, 2014.

(51) Int. Cl. H01L 31/0749; H01L 31/0216; H01L 31/0236; H01L 31/18; H01L 31/032

(52) U.S. Cl. CPC H01L 31/0749; H01L 31/02168; Y02E 10/541; H01L 31/18; H01L 31/0322; H01L 31/02366

(57) ABSTRACT

A microstructured ZnO coating that improves the performance of Cu(In,Ga)Se₂ (CIGS) photovoltaic (PV) devices via two mechanisms; it acts an antireflective layer with superior non-normal performance to thin film anti-reflective (AR) coatings, and it scatters a large fraction of incoming light at a large angle, resulting in absorption that is on average closer to the p-n junction.

### PRIORITY CLAIM

The present application is a divisional application of U.S. application Ser. No. 14/701,857, filed on May 1, 2015 by Jesse A. Frantz et al., entitled “Microstructured ZnO Coatings for Improved Performance in Cu(In,Ga)Se₂ Photovoltaic Devices,” which claimed the benefit of U.S. Provisional Application No. 61/986,940, filed on May 1, 2014 by Jesse A. Frantz et al., entitled “Microstructured ZnO Coatings for Improved Performance in Cu(In,Ga)Se₂ Photovoltaic Devices,” the entire contents of both are incorporated herein by reference.

### BACKGROUND OF THE INVENTION

### Field of the Invention

The present invention relates to a microstructured ZnO coating that improves the performance of Cu(In,Ga)Se₂ (CIGS) photovoltaic (PV) devices.

### Description of the Prior Art

CIGS thin film PV devices typically employ a transparent conductive oxide film, most commonly tin-doped indium oxide (ITO) or aluminum-doped zinc oxide (AZO), as a top electrode. Both ITO and AZO have refractive indices of around 2 at a wavelength of 500 nm, resulting in Fresnel reflections with a magnitude of approximately 11% at normal incidence. In uncoated CIGS films, therefore, a significant fraction of the incoming light is lost to reflection.

In high-performance CIGS devices, an anti-reflective (AR) coating, most often a quarter-wave of MgF₂, is employed to reduce surface reflections. This coating results in an improvement in performance at normal incidence associated with an increase in the short circuit current density, J_{SC}, of approximately 5%. Repins et al., “Required material properties for high-efficiency CIGS modules,” SPIE 7409, Thin Film Solar Technology, 74090M (2009). While single-layer AR coatings may exhibit excellent performance for a particular wavelength at a fixed incident angle, performance typically suffers away from the design wavelength and incident angle. Dobrowolski et al., “Toward perfect antireflection coatings: numerical investigation,” Appl. Opt., 41, 16, 3075-83 (2002). Since CIGS devices are often used in applications without tracking and in environments with significant scattered light, the performance at non-normal incidence is important. A coating that improves performance across both wide spectral and angular ranges is therefore desirable.

To best match the dispersion of the existing device surface, one approach is to create a structured layer of the same material present at the device/air interface, i.e. the top contact material. Such an anti-reflective surface structure (ARSS), whether its structure is ordered or random, can achieve high AR performance across a broad spectral and angular range. Florea et al., “Recent advancements in anti-reflective surface structures (ARSS) for near- to mid-infrared optics,” SPIE 8708, Window and Dome Technologies and Materials XIII, 87080P (2013). For instance, ZnO nanorods, grown with an aqueous process, have been shown to decrease the surface reflection at normal incidence when grown on CIGS devices. Shin et al., “Bottom-up grown ZnO nanorods for an antireflective moth-eye structure on CuInGaSe₂ solar cells,” Sol. Energy Mater. Sol. Cells, 95, 9, 2650-2654 (2011).

A second consideration for light collection in CIGS PV devices is the proximity to the p-n junction of photon absorption. In a typical CIGS device a p-type CIGS layer (typically about 2 μm thick) is coated with an n-type material such as CdS in order to form a p-n junction. A significant portion of the incident light is absorbed in the CIGS far (>500 nm) away from the p-n junction. If light is deflected at a large angle away from the surface normal, a larger percentage of light is absorbed close to the p-n junction, resulting in less recombination and ultimately higher efficiency.

An effect that has been observed in ZnO is surface texturing during a wet etch in HCl. A previous approach has been applied to fabricate textured bottom contacts for a-Si solar cells. Kluth et al., “Texture etched ZnO:Al coated glass substrates for silicon based thin film solar cells,” Thin Solid Films, 351, 247-253 (1999).

### BRIEF SUMMARY OF THE INVENTION

The present invention provides a microstructured ZnO coating that improves the performance of Cu(In,Ga)Se₂ (CIGS) photovoltaic (PV) devices via two mechanisms; it acts as an antireflective layer with superior non-normal performance to thin film anti-reflective (AR) coatings, and it scatters a large fraction of incoming light at a large angle, resulting in absorption that is on average closer to the p-n junction.

The performance of thin film Cu(In,Ga)Se₂ (CIGS) photovoltaics is typically degraded by light lost due to the high reflectivity of the transparent top contact and by recombination resulting from carrier generation far from the junction. Traditional antireflective (AR) coatings are insufficient to address the former issue, particularly at non-normal incidence. The present invention provides a novel microstructured ZnO coating that acts as an antireflective layer and scatters a large fraction of the incoming radiation at a large angle, resulting in absorption that is closer to the junction. This coating, formed via a wet etch process, results in performance comparable to that of uncoated films at normal incidence and an increase of up to 25% in the short circuit current and 18% in device efficiency at non-normal incidence.

The present invention has many advantages. The patterned ZnO acts an antireflective layer with superior non-normal performance to thin film AR coatings, improving CIGS PV device conversion efficiency. The patterned ZnO results in scattering of a large fraction of the incoming light at a large angle, resulting in absorption that is on average closer to the junction, improving CIGS PV device conversion efficiency. The ZnO coating is compatible with existing CIGS processing. A large scattering angle may permit thinner CIGS layers to be used in PV devices, resulting in less material usage.

These and other features and advantages of the invention, as well as the invention itself, will become better understood by reference to the following detailed description, appended claims, and accompanying drawings.

### BRIEF DESCRIPTION OF THE DRAWINGS

FIG. 1 is a schematic diagram of a CIGS device with a ZnO ARSS coating.

FIG. 2 shows SEM cross sections (top) and images taken at 20° from normal incidence of ZnO ARSS structures obtained with etch times varying from 0-30 s in 0.5% HCl solution.

FIG. 3 shows the peak-to-peak height of ARSS features, measured as a function of etch time.

FIG. 4 shows the change in J_{SC}, compared before and after ARSS deposition, as a function of illumination angle.

### DETAILED DESCRIPTION OF THE INVENTION

The present invention provides a new product that includes antireflective surface structures (ARSS) formed by chemical etching ZnO formed on top of CIGS devices. The ZnO structures improve PV device performance through a combination of two effects, the antireflective (AR) properties of the ARSS and the improvement resulting from large-angle scattering.

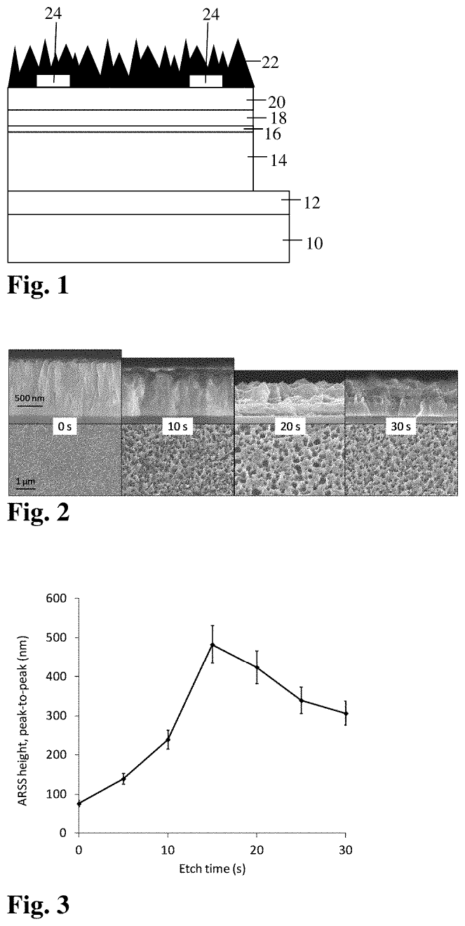

In one embodiment as depicted in FIG. 1, a soda lime glass (SLG) substrate 10 with a sputtered Mo bottom contact 12 was coated with 2 μm of CIGS 14 via single-step evaporation. Approximately 50 nm of CdS 16 was then deposited by chemical bath deposition. For the top contact, 60 nm of ZnO 18 was deposited by reactive sputtering with flowing O₂ in order to increase resistivity and transparency, and this was followed by a conductive 200 nm thick layer of aluminum-doped ZnO (AZO) 20 deposited by sputtering. Both ZnO and AZO were deposited at a substrate temperature of 200° C. Ni/Al grids, composed of 60 nm of Ni followed by 400 nm of aluminum, were deposited via electron beam evaporation. Samples were scribed by hand to obtain individual cells, each with an area of approximately 0.5 cm². PV devices were then characterized prior to ARSS coating.

The contact pads for the grids 24 were protected with photoresist, and ZnO ARSS 22 were formed on top of the devices. An 870 nm thick layer of ZnO was sputtered on top of the complete CIGS device, again with flowing O₂ and at a substrate temperature of 200° C. This layer was chemically etched in a 0.5% HCl solution at room temperature for 0-30 s resulting in a textured ZnO surface. The photoresist protecting the contact pads was removed, and devices were characterized.

Samples for cross sectional SEM analysis were obtained by mechanically breaking samples. Light J-V curves were obtained in a solar simulator under one sun, AM 1.5 G illumination calibrated using a Si reference cell. The setup was configured to allow for angular measurements of up to 60° from normal incidence. Dark current measurements were obtained with a Keithley 2400 SourceMeter in a darkened enclosure in order to evaluate diode properties of the devices.

Samples consisting of a ZnO/AZO electrode with ARSS coatings were etched for times varying from 0-30 s in dilute HCl. Samples were visibly hazy in transmission after etching. Spectroscopic measurements of etched ZnO films deposited on glass substrates showed an absolute decrease of ˜5% from 350-1200 nm in specular reflection.

SEM images showing cross sections and images taken at 20° from normal incidence are shown in FIG. 2. Prior to etching, the ZnO exhibited a small amount of surface roughness that increased rapidly with etch time. Features were subwavelength and consistent across the etched surface. For the 20 and 30 s etches, some features extended through the entire ZnO film but not the underlying electrode, indicating that the etch rate of AZO is smaller than that of ZnO. This is fortuitous in that the AZO layer acts as a barrier, preventing the HCl etch from damaging other layers of the device. This result was consistent with dark current measurements, made before and after ARSS deposition, showing that the diode properties of the junction were preserved.

The depth of ARSS features, measured peak-to-peak from cross-sectional SEM images, is shown in FIG. 3. Feature height initially increased with etch time, peaks at approximately 500 nm for an etch time of 15 s, and decreased gradually with further etching. The decrease in thickness resulted from etching of the tallest features while no ZnO remained to etch on the bottom. Feature height could potentially be increased further by using a thicker ZnO film.

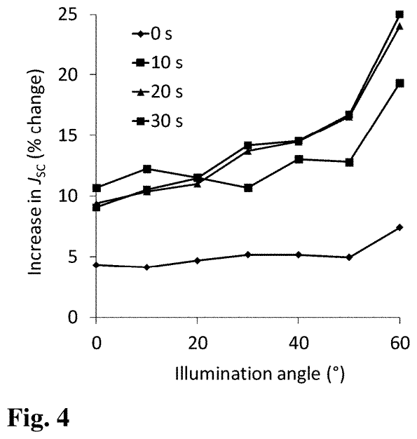

Light J-V measurements were obtained for films with varying etch times for angles ranging from 0−60°. The open circuit voltage, V_{OC}, and fill factor (FF) were found to decrease slightly, by <10%, for all etch times and angles. This was attributes to the extra anneal that occurred during ZnO deposition. Further optimization of ZnO deposition parameters is expected to reduce this effect. The most pronounced change, however, was a dramatic increase in J_{SC}. FIG. 4 shows J_{SC} as a function of incident angle for varying etch times. A slight increase of approximately 5% was evident for the un-etched sample for all angles—potentially resulting from the extra anneal or from scattering caused by the intrinsic texture of the un-etched ZnO surface. The etched samples each exhibited a J_{SC} increase of approximately 10% at normal incidence that further increased with incident angle. The J_{SC} of the 20 s sample increased most—by 14% at 30° and 25% at 60°.

As a result of the increase in J_{SC} of the 20 s sample, its performance improved the most of all devices. Table 1 shows PV parameters for this sample. While the efficiency, increased only slightly, from 10.4% to 10.5% at normal incidence. It increased more significantly for non-normal incidence with a relative improvement of approximately 18% for 60° illumination. This is consistent with decreased surface reflection.

TABLE 1
Device Results for 20 s Etched Sample

| Condition | V_{OC} (mV) | J_{SC} (mA/cm²) | FF (%) | η (%) |
|---|---|---|---|---|
| 0° Before | 520.3 | 30.9 | 64.6 | 10.4 |
| 0° After | 514.7 | 33.8 | 60.1 | 10.5 |
| 30° Before | 517.9 | 25.5 | 65.7 | 8.7 |
| 30° After | 512.8 | 29.0 | 60.8 | 9.0 |
| 60° Before | 503.5 | 13.3 | 66.7 | 4.5 |
| 60° After | 503.5 | 16.5 | 64.0 | 5.3 |

It is significant to note that the increase in J_{SC} at 60° is greater than the 17% Fresnel reflection expected at this angle. Thus, the AR properties of the ARSS alone are insufficient to explain the increased current. It is clear that the scattering properties of the coating, resulting in absorption closer to the junction, are necessary to fully explain the increase in J_{SC} at large angles.

The PV absorber could be a different thin film PV absorber, such as CuInSe₂ (CIS), CuGaSe₂ (CGS), Cu₂ZnSn(S,Se)₄ (CZTS), CdTe, amorphous Si, or organics.

A mask could be deposited on the ZnO prior to etching in order to affect the layer's post-etching morphology.

Deposition parameters for the ZnO film such as substrate temperature, partial pressure, and deposition power could be adjusted in order to affect the layer's post-etching morphology.

The oxygen content of the ZnO film could be varied by adjusting target composition or O₂ flow during deposition in order to affect the layer's post-etching morphology.

The ZnO film could doped with an agent that affects grain formation—resulting in changes in grain size, shape or orientation—in order to affect the layer's post-etching morphology.

The above descriptions are those of the preferred embodiments of the invention. Various modifications and variations are possible in light of the above teachings without departing from the spirit and broader aspects of the invention. It is therefore to be understood that the claimed invention may be practiced otherwise than as specifically described. Any references to claim elements in the singular, for example, using the articles “a,” “an,” “the,” or “said,” is not to be construed as limiting the element to the singular.

What is claimed as new and desired to be protected by Letters Patent of the United States is:

1. A photovoltaic device, comprising:
a p-type layer on a substrate;
an n-type layer on the p-type layer, forming a p-n junction;
a layer of ZnO on the n-type layer;
a layer of aluminum-doped ZnO (AZO) on the ZnO; and
a continuous microstructured ZnO topmost layer on the AZO, wherein the continuous microstructured ZnO topmost layer comprises antireflective surface structures on the AZO layer and scatters incoming light, increasing absorption of scattered light close to the p-n junction.

2. The photovoltaic device of claim 1, wherein the substrate comprises glass with a Mo bottom contact.

3. The photovoltaic device of claim 1, wherein the p-type layer is about 2 μm thick.

4. The photovoltaic device of claim 1, wherein the n-type layer is about 50 μm thick.

5. The photovoltaic device of claim 1, wherein the ZnO layer on the n-type layer is about 60 nm thick.

6. The photovoltaic device of claim 1, wherein the AZO layer is about 200 nm thick.

7. The photovoltaic device of claim 1, wherein the ZnO layer, the AZO layer, and the continuous microstructured ZnO topmost layer are deposited on the substrate at a substrate temperature of 200° C.

8. The photovoltaic device of claim 1, wherein the antireflective surface structures in the continuous microstructured ZnO topmost layer have a peak-to-peak height of about 500 nm or less.

9. The photovoltaic device of claim 1, wherein the p-type layer comprises Cu(In, Ga)Se₂ (CIGS), CuInSe₂ (CIS), CuGaSe₂ (CGS), Cu₂ZnSn(S,Se)₄ (CZTS), CdTe, amorphous Si, or any combination thereof.

10. The photovoltaic device of claim 1, where the n-type material is CdS.

11. A photovoltaic device, made by the method comprising:
coating a substrate with a p-type layer;
depositing an n-type layer on the p-type layer, forming a p-n junction;
depositing a layer of ZnO on the n-type layer;
depositing a layer of aluminum-doped ZnO (AZO) on the ZnO;
depositing a continuous top layer of ZnO on the AZO; and
etching the ZnO top layer to form a textured continuous ZnO topmost layer comprising subwavelength surface structures;
wherein the textured continuous ZnO topmost layer comprises antireflective surface structures on the AZO layer and scatters incoming light, increasing absorption of scattered light close to the p-n junction.

12. The photovoltaic device of claim 11, wherein the substrate comprises glass with a Mo bottom contact.

13. The photovoltaic device of claim 11, wherein the p-type layer is about 2 μm thick.

14. The photovoltaic device of claim 11, wherein the n-type layer is about 50 μm thick.

15. The photovoltaic device of claim 11, wherein the ZnO layer on the n-type layer is about 60 nm thick.

16. The photovoltaic device of claim 11, wherein the AZO layer is about 200 nm thick.

17. The photovoltaic device of claim 11, wherein the ZnO layer, the AZO layer, and the continuous ZnO top layer are deposited on the substrate at a substrate temperature of 200° C.

18. The photovoltaic device of claim 1, wherein the antireflective surface structures in the textured continuous ZnO topmost layer have a peak-to-peak height of about 500 nm or less.

19. The photovoltaic device of claim 1, wherein the p-type layer comprises Cu(In, Ga)Se₂ (CIGS), CuInSe₂ (CIS), CuGaSe₂ (CGS), Cu₂ZnSn(S,Se)₄ (CZTS), CdTe, amorphous Si, or any combination thereof.

20. The photovoltaic device of claim 1, where the n-type material is CdS.
